(19) United States
(12) Patent Application Publication
(10) Pub. No.: US 2022/0270956 A1
(43) Pub. Date: Aug. 25, 2022

(54) ELECTRICAL AND/OR ELECTRONIC COMPONENT AND CONTACT SYSTEM

(71) Applicant: Robert Bosch GmbH, Stuttgarf (DE)

(72) Inventors: Thomas Suenner, Neustadt (DE); Christian Schiele, Munich (DE); Reiner Hemmert, Reutlingen (DE)

(21) Appl. No.: 17/625,151

(22) PCT Filed: Jul. 23, 2020
(86) PCT No.: PCT/EP2020/070758

§ 371 Date: Jan. 6, 2022

(30) Foreign Application Priority Data
Jul. 25, 2019 (DE) 10 2019 211 077.0

(51) Int. Cl. H01L 23/495; H05K 1/18; H01L 21/48; H05K 3/32

(52) U.S. Cl. CPC H01L 23/49524; H05K 1/18; H01L 21/4825; H05K 3/328; H05K 2201/1078; H05K 2201/10916; H05K 2201/10833; H01L 23/3107

(57) ABSTRACT

An electrical and/or electronic component including at least one electrical outside connecting contact. This contact is a terminal lug, which is attached at one side, for the electrical contacting with a contacting partner. The terminal lug includes a connecting side including a planar connecting surface for the electrical contacting. The exposed end of the terminal lug includes a bending leg, which is bent out of the plane by a compensating angle toward the connecting side. The bending leg includes the connecting surface. The terminal lug is designed such that, when a contacting partner, which is planar at least in this area, makes site contact with the free end of the bending leg with a force applied from the connecting side, a position orientation of the connecting surface is adaptable counter to the compensating angle until a gap-free contact is made between the connecting surface and the planar contacting partner.

### FIELD

The present invention relates to an electrical and/or electronic component, to a contact system including the electrical and/or electronic component, and to a method for forming the contact system.

### BACKGROUND INFORMATION

It is generally conventional to establish a mechanical and an electrical connection of metallic workpieces with the aid of welding, for example with the aid of laser welding. This is used, among other things, when welding together power contacts of power modules within electronic power circuits, for example. In the process, the two weld partners, for example the power contact and a connecting point of the electronic circuit, have to be brought together very closely, in general below a gap width of 100 μm. If gap distances are larger, metallic spatter may otherwise occur during laser welding, all the way to non-welded contacts. Additionally, poorly welded or non-welded contacts, in particular, are visually hardly discernible, and they may thus represent a source of defects for malfunctions. An ideal zero gap between the weld partners may be easily achieved from a technical perspective in that both weld partners are compressed with the aid of a tongs-like device, except for a gap-free site contact, under elastic and/or plastic deformation. In particular, in the case of very compact electronic circuits, a necessary space for such a device is not always present. Furthermore, such a device is often difficult to handle since an access has to occur from both sides of the weld partners. In addition, a counter support is generally required for the welding device, for which purpose a support surface has to be provided, for example on the carrier substrate of the electronic circuit.

### SUMMARY

It is an object of the present invention to provide weld contacts of electrical and/or electronic components within compact circuits to be as gap-free as possible.

This object may be achieved by an electrical and/or electronic component, by a contact system including the electrical and/or electronic component, and by a method for forming the contact system, in accordance with example embodiments of the present invention.

The present invention proceeds from an electrical and/or electronic component including at least one electrical outside terminal contact. In accordance with an example embodiment of the present invention, the outside terminal contact is designed as a terminal lug, which is attached at one side, for the electrical contacting with a contacting partner. The terminal lug includes a connecting side including a planar connecting surface for the electrical contacting. It therefore corresponds, in the mechanical model, to a bending beam which is clamped on one side. The terminal lug is preferably formed of a sheet metal material, in particular as a stamped metal sheet or laser metal sheet, for example made up of copper, and contacts an electrical functional area of the component. As an outside terminal contact contacted from the outside, it allows the electrical functional area to be integrated, for example, within an electronic circuit. The exposed end of the terminal lug includes a bending leg, which is bent out of the plane by a compensating angle toward the connecting side. The bending leg includes the connecting surface. The terminal lug is furthermore designed in such a flexible manner that, when a contacting partner, which is planar at least in this area, makes site contact with the free end of the bending leg with a force applied from the connecting side, a position orientation of the connecting surface is adaptable at least counter to the compensating angle until a gap-free contact is made between the connecting surface and the planar contacting partner. With respect to a weld contact to be formed, the terminal lug is thus advantageously previously prepared as an optimized welding partner. By orienting the bending leg, on the connecting side, counter to a force application acting from this side, for example with the aid of a welding mask resting at least indirectly thereon, an initial site contact of a planar contacting partner, for example a connecting clip, which is moved relatively from the connecting side toward the terminal lug, is made possible in the area of the free end of the terminal lug, i.e., the bending leg. In the process, first a gap may be formed during the initial site contact between the terminal lug and the contacting partner, which extends in a wedge-shaped manner to the initial site contact point. This gap may now be reduced to a gap-free contact in that a forced bending of the terminal lug is effectuated with the aid of a further force application, for example by a further relative movement of the described welding mask, preferably a rectilinear relative movement. Due to the continued bending of the terminal lug, the surface position of the connecting surface rotates counter to the compensating angle toward the plane of the contacting partner, all the way to the planar and thus gap-free contact. This then corresponds to an optimal welding position in which a gap-free weld contact is formable with the aid of a welding process. The provided compensating angle thus enables the reliable necessary position correction of the connecting surface and compensates for malpositions, for example due to assembly and/or manufacturing tolerances. Since only a one-sided force application from the connecting side is required, the formation of a weld contact within a very space-constrained electronic circuit is made possible without an otherwise required counter site.

The measures disclosed herein allow advantageous refinements of and improvements on the electronic assembly according to the present invention.

In one advantageous specific embodiment of the electrical and/or electronic component of the present invention, the compensating angle has a value in a range of 0.5° to 5°, preferably in a range of 0.5° to 1.5°. It has been shown that, in this range, many initial malpositions which are subject to tolerances may already be compensated for by the position correction of the connecting surface which is made possible, and the manufacturing times for forming a gap-free weld contact may be kept small due to the distances being kept short until the optimal weld position is reached. Reaching the optimal weld position preferably takes place by a fully elastic flexibility of the terminal lug, at least however, alternatively, preferably by a partially elastic flexibility of the terminal lug. In this way, it is also possible to keep the application forces for the position correction of the connecting surface small so that damage may be precluded during the formation of a weld contact.

In one advantageous refinement of the electrical and/or electronic component, the terminal lug includes a terminal leg. It opens, with its one end, via a bending area into the bending leg and, at its other end, then includes the one-sided attachment of the terminal lug within the electrical and/or electronic component. The terminal lug advantageously only includes one bending point, so that the preparation of the terminal lug may be implemented very cost-effectively for a weld contact to be optimally designed. In the process, the bend may preferably be introduced into an original terminal lug made up of a planar sheet material so that, in particular, a rectilinearly extending terminal leg remains. It is generally advantageous for a longitudinal extension of the terminal leg to be several times shorter than a longitudinal extension of the bending leg, in particular about 2 to 20 times shorter, and preferably 5 to 10 times shorter. In this way, a flexibility of the terminal lug increasingly results more or less solely from the bending leg. The bending point then approximately represents the function of a rigid swivel joint. Furthermore, the optimal welding position may be set more precisely.

In one preferred specific embodiment of the electrical and/or electronic component of the present invention, it includes a fixed housing, from which the terminal lug, which is attached at one side, protrudes. The housing is preferably made of a plastic material, in particular a mold material. In the process, the terminal lug, at its attached end, is, further preferably, surrounded or enclosed on all sides by the plastic material. With the aid of the housing, increased application forces acting on the terminal lug may then advantageously be absorbed without damage by the electrical and/or electronic component.

Further advantages arise in one specific embodiment of the electrical and/or electronic component of the present invention which includes, for example, an underside terminal and/or support side to a carrier substrate. The terminal lug is situated spaced apart toward the underside terminal and/or support side. In a top view onto the terminal or support side, the terminal lug, projecting laterally therefrom, is furthermore attached at one side within the electrical and/or electronic component. In the process, the bending leg points away from the terminal and/or support side. In this way, overall a free access to the terminal lugs is provided for a one-sided force application from the connecting side. Moreover, as a result of the spacing, an unimpaired bending of the terminal lug in the direction of the terminal or support side is made possible. A housed electrical and/or electronic component preferably includes an exit point of a terminal leg of the terminal lug out of the housing in a terminal plane parallel to the terminal or support side. Further preferably, the terminal leg is situated within this terminal plane up to the bending point, while the bending leg is bent, in particular, perpendicularly to a longitudinal extension of the terminal leg out of the terminal plane in the direction of the connecting side of the terminal lug.

The electrical and/or electronic component is, in general, preferably designed as a power module, in particular, in the form of a mold module. In the process, the terminal lug is designed as a power contact. The electrical and/or electronic component may overall also include two, three or even more such terminal lugs exclusively or in addition to at least one differently designed outside terminal contact.

The present invention also provides a contact system, including at least one electrical and/or electronic component in at least one of the above-described specific embodiments of the present invention, an, in particular, gap-free connecting contact being formed between the terminal lug in the area of the connecting surface and a planar contacting partner which, at least in the formed connecting area, is gap-free. Such a connecting contact represents a connection, for example to an electronic circuit, which is functionally reliable over the service life. The connecting contact is, in particular, designed as a weld contact in the process. During the use of a laser process, in particular, a laser weld contact is obtained.

In one preferred specific embodiment of the contact system of the present invention, it is designed as part of an electronic circuit on a carrier substrate. The contacting partner is, in particular, a connecting clip which connects the terminal lug and a terminal point of the electronic circuit to one another, bridging the same. The connecting clip is, for example, a stamped sheet metal part, in particular, made up of copper. In addition to planar surfaces in the connecting areas to the terminal lug or to the terminal point, the connecting clip may include one or multiple bend(s), for example to span an application-induced vertical offset between the terminal lug and the connecting point of the electronic circuit. The connecting clip may furthermore include recesses, in particular, in the form of longitudinal slots between the connecting points. In this way, the connecting clip is given sufficient mechanical elasticity to enable an alignment of the provided joining surfaces in the connecting areas by a bending and/or torsion up to a gap-free contact with the respective weld partner.

The electronic circuit is preferably designed as a B2 or B6 bridge, in particular, as a circuit part of an inverter.

The present invention also provides a method for forming a contact system according to at least one of the above-described specific embodiments. In accordance with an example embodiment of the present invention, the method includes the following method steps:
a) providing an electrical and/or electronic component according to at least one of the above-described specific embodiments, for example in that it is situated via its, for example, underside terminal and/or support side on a carrier substrate;
b) forming an initial system in that a planar support side of a contacting partner is situated, from the connecting side of the terminal lug, in site contact with the exposed end of the bending leg, and a welding mask is placed onto a welding side situated opposite the support side of the contacting partner;
c) applying a force to the initial system by a push-down force, in particular with the aid of a preferably rectilinear relative movement of the welding mask, in such a way that a changed position orientation of the connecting surface occurs at least counter to the compensating angle of the bending leg due to a yielding of the terminal lug in the force direction;
d) maintaining a welding position in which the connecting surface of the terminal lug and the support side of the contacting partners rest planarly against one another; and
e) forming a weld contact, for example with the aid of lasers on the welding side of the contacting partner, as a gap-free connecting contact between the terminal lug and the contacting partner.

In one advantageous specific embodiment of the method of the present invention, the contacting partner is designed as a connecting clip, an end of the connecting clip which is spaced apart from the site contact being held in a stationary manner prior to or during method step b). This may take place, for example, with the aid of a holding tool, which receives and fixes the described end in a stationary manner. As an alternative, a stationary fixation takes place by an at least indirect integral or force-fit and/or form-locked connection to the carrier substrate. As a result of the one-sided fixation, the terminal lug and the connecting clip may align with one another, up to a gap-free contact in the connecting area, solely by the force application and bending.

In one advantageous refinement of the method of the present invention, a further connecting contact is formed between the connecting clip and a terminal point of an electronic circuit, in particular as a weld contact, between the end of the connecting clip held in a stationary manner and the connecting contact with the terminal lug to be formed or having been formed. The further connecting contact is preferably formed chronologically before, after or together with the connecting contact between the connecting clip and the terminal lug.

### BRIEF DESCRIPTION OF THE DRAWINGS

Further advantages, features and details of the present invention are derived from the following description of preferred exemplary embodiments and based on the figures.

FIG. 1 shows an electrical and/or electronic component including an end-sided bending leg within a terminal lug, which is attached at one side, as an outside contact terminal in a side view, in accordance with an example embodiment of the present invention.

FIG. 2 shows an initial system including an electrical and/or electronic component from FIG. 1 in an initial contact with a contacting partner including an initial contact site point at the exposed end of the bending leg of the terminal lug in a side view, in accordance with an example embodiment of the present invention.

FIG. 3 shows a contact system resulting from the initial system according to FIG. 2 after a force application and welding, forming a gap-free weld contact between the terminal lug and the contacting partner in a side view, in accordance with an example embodiment of the present invention.

FIG. 4 shows a contact system within an electronic circuit, in particular, an inverter circuit, in a perspective illustration, in accordance with an example embodiment of the present invention.

### DETAILED DESCRIPTION OF EXAMPLE EMBODIMENTS

In the figures, functionally equivalent components are each denoted by identical reference numerals.

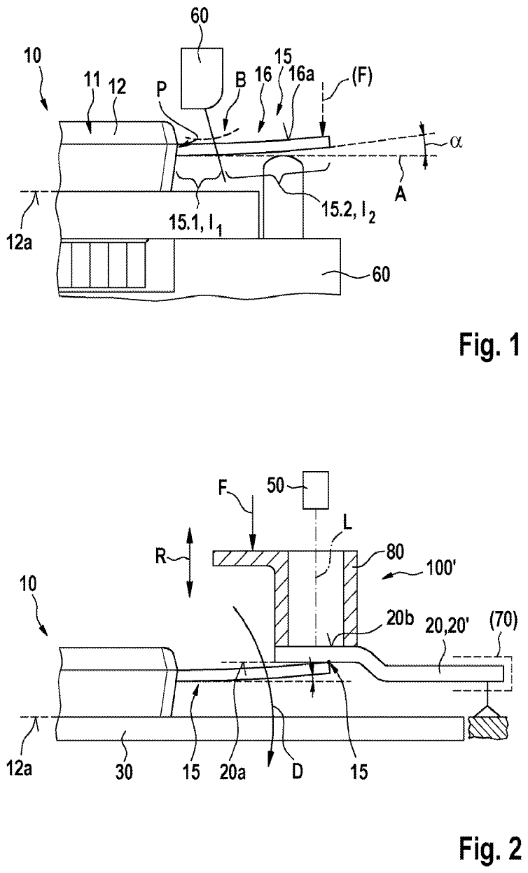

FIG. 1 shows an electrical and/or electronic component 10 in a side view. It includes an outside contact terminal 15, which is designed as a terminal lug attached at one side. The attachment takes place to a component base body 11, via which terminal lug 15 is contacted with an electrical functional area of component 10. Terminal lug 15 is formed of a sheet metal material by way of example, for example of a copper sheet. In the present exemplary embodiment, terminal lug 15 includes a bending point B and, via the longitudinal extension of terminal lug 15, thus sectionally divides the terminal lug at least into a longitudinal section I1 of a terminal leg 15.1 and an adjoining longitudinal section I2 of a bending leg 15.2. At its one end, terminal leg 15.1 is thus attached at one side to component base body 11 and opens via the other end, starting at bending point B, into the one end of bending leg 15.2. The other end of bending leg 15.2 is exposed. In the process, bending leg 15.2 is bent by a compensating angle α out of a connecting plane A in which, for example prior to the bending, a uniform surface side of the still unbent terminal lug 15 was situated. The bending takes place toward a connecting side 16 of terminal lug 15. An electrical connection of terminal lug 15 as an outside terminal contact to a contacting partner later takes place via connecting side 16 with the aid of a connecting contact. For this purpose, bending leg 15.2 includes a connecting surface 16a via which the connecting contact is then formable. Terminal leg 15.1 is preferably situated with its one surface side in terminal plane A. Further preferably, electrical and/or electronic component 10 includes a housing 12, in particular made of plastic. Housing 12 is then, for example, formed of a mold material. Electrical and/or electronic component 10 also includes an underside terminal or support side 12a, via which component 10 may be situated on a carrier substrate 30. Terminal lug 15 emerges from housing 12 in the area of terminal leg 15.1 in an exit point P. Exit point P is, in particular, situated in terminal plane A, so that exit point P and the terminal plane are situated in parallel, spaced apart with respect to underside terminal or support side 12a. Overall, terminal lug 15 is shown in an exemplary manner as a bending beam which is clamped on one side. During a force application with a force F from connecting side 16a, for example on the exposed end of bending leg 15.2, a preferably fully elastic or at least partially elastic bending in the direction of underside terminal or support side 12a of component 10 takes place. In the process, a position orientation of connecting surface 16a also changes, at least counter to compensating angle α. Longitudinal section I1 of terminal leg 15.1 is preferably designed to be several times shorter than longitudinal section I2 of bending leg 15.2, in particular 2 to 20 times shorter, preferably 5 to 10 times shorter. In this way, an increasing rotary movement about bending point B than in the essentially rigid swivel joint occurs during the force application. For example, bending point B is introduced into a still unbent terminal lug 15 by a bending tool 60. In the process, tool 60 includes, for example, a fixed stop and a displaceable bending pin, the bending pin, as a result of a force movement in contact with terminal lug 15, bending the terminal lug against the fixed stop at bending point B toward connecting side 16. Only one terminal lug in the described design is visible in the side view of FIG. 1. In principle, electrical and/or electronic component 10 may include further identical or similar terminal lugs 15, exclusively or in addition to at least a differently designed outside terminal contact.

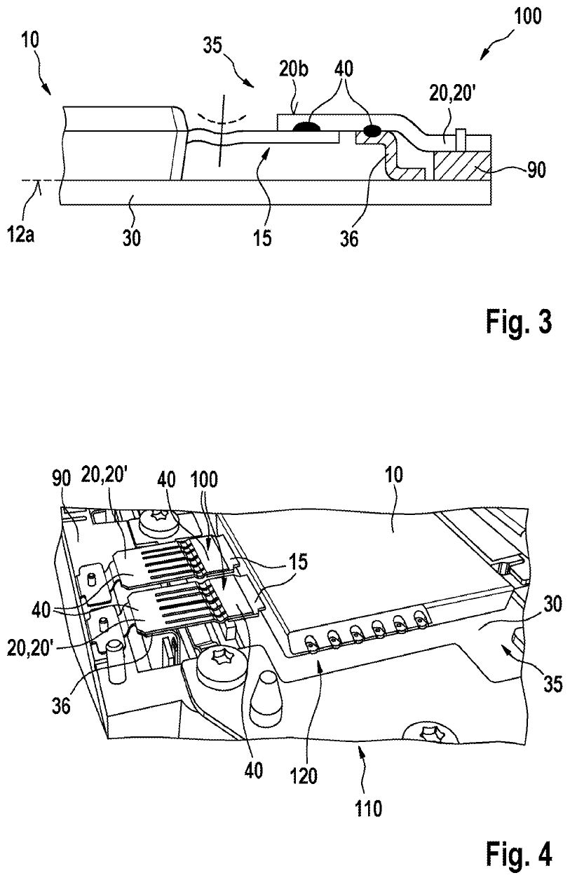

For forming a contact system 100 including electrical and/or electronic component 10 including a connecting contact 40 to a contacting partner 20, a procedure is described hereafter with the aid of FIGS. 2 and 3. First, electrical and/or electronic component 10 is provided for a connecting process. For this purpose, it is situated, for example, via its underside terminal or connecting side 12a on a carrier substrate 30, for example with the aid of a sintered or soldered contact. A wide variety of substrate types may be used as carrier substrate 30, for example a lead frame, a rigid or flexible circuit board, a double bonded copper (DBC) substrate, an insulated metal substrate (IMS) substrate, an active metal brazing (AMB) substrate, a low temperature co-fired ceramic (LTCC) substrate, or the like. A starting system 100′ is formed thereafter. In the process, a planar area of a support side 20a of a contacting partner 20 to be connected is brought into an initial contact with the free end of bending leg 15.2. Contacting partner 20 may, for example, be situated by a placement process, coming from connecting side 16 of terminal lug 15, in a position in which support side 20a of the contacting point makes contact with the end of the bending leg in an initial site point E. In this position, contacting partner 20 is held in a stationary manner at an end of contacting partner 20 which is spaced apart from initial site point E, for example by a holding tool 70 or by an integral or form-locked and/or force-fit connection, for example to carrier substrate 30. Simultaneously with the placement process or alternatively thereafter, a welding mask 80 is placed onto a welding side 20b of contacting partner 20 situated opposite support side 20a. An initial site contact may also be formed after having first placed welding mask 20 onto welding side 20b of a contacting partner 80 which is held in a stationary manner on one side, and the mask is displaced in the direction of connecting side 16 of terminal lug 15 until initial site point E has been reached.

In principle, after an initial site point E is present, a force is applied to initial system 100′ by a further, for example rectilinear, relative movement R of welding mask 20 in the direction of connecting side 16 of terminal lug 15. As a result of the acting push-down force F, terminal lug 15 yields elastically or at least partially elastically in the direction of carrier substrate 20 due to an at least proportionate rotary movement D, by which also a changed position orientation of connecting surface 16a occurs at least counter to compensating angle α of bending leg 15.2. Relative movement R of welding mask 80 is first maintained in a welding position in which connecting surface 16a of terminal lug 15 and support side 20a of contacting partner 20 rest planarly against one another. Thereupon, a weld contact 40 is formed as a connecting contact with the aid of a welding process, while maintaining the welding position. The welding process takes place, for example, with the aid of a laser 50, whose laser radiation L is directed at welding side 20b of contacting partner 20. Welding mask 80 is preferably configured in a tubular manner and, in particular, has a wall height by which metallic spatter during laser welding may be prevented from spreading outside welding mask 80.

FIG. 3 shows the formed contact system 100 including the then gap-free weld contact 40 between terminal lug 15 and contacting partner 20 in a side view after welding mask 80 has been removed. Contacting partner 20 is then, for example, a connecting clip 20′, which, in particular, is designed as a stamped sheet metal part, preferably made up of copper. In contrast to the illustration in FIG. 2, the end of connecting clip 20′ spaced apart from weld contact 40 is indirectly connected via a frame element 90 to carrier substrate 30 in a force-fit and/or form-locked manner, and is thereby held in a stationary manner, for example via a hole-pin connection. In addition, a further weld contact 40 is formed between the end of connecting clip 20′ which is held in a stationary manner and the formed weld contact 40 including terminal lug 15, as a connecting contact between connecting clip 20′ and terminal point 36 of an electronic circuit 35 situated on carrier substrate 30. The further connecting contact 40 may be formed chronologically before, after or together with the connecting contact between connecting clip 20′ and terminal lug 15 with the aid of laser 50.

FIG. 4 shows the contact system from FIG. 3 in a perspective illustration, for example as a circuit part of an inverter 110. Electronic circuit 35 includes a B2 or B6 bridge, which is formed by at least one described electrical and/or electronic component 10, in particular as a power module, preferably in the form of a mold module. In the present exemplary embodiment, two power contacts 15 situated on the same side are connected in each case to a connecting clip 20′ with the aid of a gap-free weld contact 40, forming contact system 100.

1-15. (canceled)

16. An electrical and/or electronic component, comprising:
at least one electrical outside terminal contact configured as a terminal lug, attached at one side, for electrical contacting with a planar contacting partner, the terminal lug including a connecting side including a planar connecting surface for the electrical contacting;
wherein an exposed end of the terminal lug includes a bending leg, which is bent by a compensating angle out of a plane toward the connecting side, the bending leg including the connecting surface, and the terminal lug being configured in such a flexible manner that, when the planar contacting partner makes site contact with a free end of the bending leg with a force applied from the connecting side, a position orientation of the connecting surface is adaptable at least counter to the compensating angle until a gap-free contact is made between the connecting surface and the planar contacting partner.

17. The electrical and/or electronic component as recited in claim 16, wherein the compensating angle has a value in a range of 0.5° to 5°.

18. The electrical and/or electronic component as recited in claim 16, wherein the compensating angle has a value in a range of 0.5° to 1.5°.

19. The electrical and/or electronic compartment as recited in claim 16, wherein the terminal lug includes a terminal leg which extends rectilinearly and which, with its one end, opens via a bending point into the bending leg and, at its other end, includes a one-sided attachment of the terminal lug within the electrical and/or electronic component.

20. The electrical and/or electronic compartment as recited in claim 19, wherein a longitudinal extension of the terminal leg is several times shorter than a longitudinal extension of the bending leg.

21. The electrical and/or electronic compartment as recited in claim 19, wherein a longitudinal extension of the terminal leg is 2 to 20 times shorter than a longitudinal extension of the bending leg.

22. The electrical and/or electronic compartment as recited in claim 19, wherein a longitudinal extension of the terminal leg is 5 to 10 times shorter than a longitudinal extension of the bending leg.

23. The electrical and/or electronic compartment as recited in claim 16, wherein the electrical and/or electronic component includes a housing, from which the terminal lug, which is attached at one side, protrudes.

24. The electrical and/or electronic component as recited in claim 16, wherein the electrical and/or electronic component includes a terminal and/or support side to a carrier substrate, the terminal lug being situated spaced apart from the terminal and/or support side and, in a top view onto the terminal or support side, projecting laterally therefrom, being attached thereto on one side within the electrical and/or electronic component, the bending leg pointing away from the terminal and/or support side.

25. The electrical and/or electronic component as recited in claim 16, wherein the electrical and/or electronic component is a power module.

26. The electrical and/or electronic component as recited in claim 16, wherein the electrical and/or electronic component is a mold module.

27. A contact system, comprising:
at least one electrical and/or electronic component including:
at least one electrical outside terminal contact configured as a terminal lug, attached at one side, for electrical contacting with a planar contacting partner, the terminal lug including a connecting side including a planar connecting surface for the electrical contacting,
wherein an exposed end of the terminal lug includes a bending leg, which is bent by a compensating angle out of a plane toward the connecting side, the bending leg including the connecting surface, and the terminal lug being configured in such a flexible manner that, when the planar contacting partner makes site contact with a free end of the bending leg with a force applied from the connecting side, a position orientation of the connecting surface is adaptable at least counter to the compensating angle until a gap-free contact is made between the connecting surface and the planar contacting partner;
wherein the gap-free connecting contact is formed between the terminal lug in an area of the connecting surface and the planar contacting partner.

28. The contact system as recited in claim 27, wherein the connecting contact is a weld contact or a laser weld contact.

29. The contact system as recited in claim 27, wherein the contact system is part of an electronic circuit on a carrier substrate, the planar contacting partner being a connecting clip, which connects the terminal lug and a terminal point of the electronic circuit to one another, bridging them.

30. The contact system as recited in claim 29, wherein the electronic circuit is a B2 or B6 bridge as a circuit part of an inverter.

31. A method for forming a contact system, comprising the following method steps:
a) providing an electrical and/or electronic component situated via its underside terminal and/or support side on a carrier substrate, the electrical and/or electronic component including:
at least one electrical outside terminal contact configured as a terminal lug, attached at one side, for electrical contacting with a planar contacting partner, the terminal lug including a connecting side including a planar connecting surface for the electrical contacting;
wherein an exposed end of the terminal lug includes a bending leg, which is bent by a compensating angle out of a plane toward the connecting side, the bending leg including the connecting surface, and the terminal lug being configured in such a flexible manner that, when the planar contacting partner makes site contact with a free end of the bending leg with a force applied from the connecting side, a position orientation of the connecting surface is adaptable at least counter to the compensating angle until a gap-free contact is made between the connecting surface and the planar contacting partner;
b) forming an initial system in that a planar support side of the contacting partner is situated, from the connecting side of the terminal lug, in site contact with the exposed end of the bending leg, and a welding mask is placed onto a welding side situated opposite the support side of the contacting partner;
c) applying a force to the initial system by a push-down force, with the aid of a rectilinear relative movement of the welding mask, in such a way that a changed position orientation of the connecting surface, at least counter to the compensating angle of the bending leg, occurs due to a yielding of the terminal lug in the force direction;
d) maintaining a welding position in which the connecting surface of the terminal lug and the support side of the contacting partner rest planarly against one another; and
e) forming a weld contact on the welding side of the contacting partner, as a gap-free connecting contact between the terminal lug and the contacting partner.

32. The method as recited in claim 31, wherein the weld contact is formed a laser.

33. The method as recited in claim 31, wherein the contacting partner is a connecting clip, an end of the connecting clip, which is spaced apart from the site contact, being held in a stationary manner prior to or during method step b), with the aid of a holding tool or an at least indirect integral or force-fit and/or form-locked connection to the carrier substrate.

34. The method as recited in claim 33, wherein a further connecting contact is formed between the connecting clip and a terminal point of an electronic circuit, as a weld contact, between the end of the connecting clip held in a stationary manner and the connecting contact with the terminal lug to be formed or having been formed.

35. The method as recited in claim 34, wherein the further connecting contact is formed chronologically before or after or together with the connecting contact between the connecting clip and the terminal lug.
